(19) United States
(12) Patent Application Publication
(10) Pub. No.: US 2026/0212081 A1
(43) Pub. Date: Jul. 23, 2026

(54) A SYSTEM FOR DETERMINING INDIVIDUAL PRODUCT AMOUNTS OF A PLURALITY OF CHEMICAL REACTORS

(71) Applicant: BASF SE, Ludwigshafen am Rhein (DE)

(72) Inventors: Felix Wenzl, Ludwigshafen am Rhein (DE); Michael Willenbacher, Ludwigshafen am Rhein (DE)

(73) Assignee: BASF SE, Ludwigshafen am Rhein (DE)

(21) Appl. No.: 19/139,482

(22) PCT Filed: Dec. 11, 2023
(86) PCT No.: PCT/EP2023/085179

§ 371 Date: Jun. 16, 2025

(30) Foreign Application Priority Data
Dec. 16, 2022 (EP) 22214118.6

(51) Int. Cl. G06F 30/27

(52) U.S. Cl. CPC G06F 30/27

(57) ABSTRACT

The invention relates to a system (100) for determining individual product amounts of a plurality of chemical reactors (11, 12, . . . , 1K) contributing to a combined product amount. The system comprises a measurements providing unit (101) providing measured individual reactant amounts for each reactor, and an artificial intelligence providing unit (102) providing artificial intelligences (21, 22, . . . , 2K) for each reactor that are trained to provide, upon receiving individual reactant amounts for the reactors as input, individual product amounts of the reactors as output that combine to a combined product amount associated with the individual reactant amounts received as input. The system further comprises an individual product amount determining unit (103) determining individual product amounts for the reactors based on the measured individual reactant amounts and the trained artificial intelligences. The system allows for increasing a chemical production efficiency whenever a plurality of reactors contribute to a combined product amount.

### FIELD OF THE INVENTION

The invention relates to a system, a method and a computer program for determining individual product amounts of a plurality of chemical reactors contributing to a combined product amount.

### BACKGROUND OF THE INVENTION

It is often necessary in chemical production processes that a reaction is simultaneously executed in more than one chemical reactor. Nevertheless, often only a single product output may be supplied, i.e. a single product amount that is combined from the product amounts produced by the individual reactors. For instance, conduits from the individual reactors may join to a common supply conduit, wherein the product may only be accessible via the common supply conduit. In such a case, if the individual product amounts of the plurality of reactors are not measurable, it can be difficult to control the individual reactors. However, a sub-optimal control of the reactors can lead to an inefficient production process.

### SUMMARY OF THE INVENTION

It is an object of the invention to allow for increasing an efficiency of chemical production processes in which a plurality of chemical reactors contribute to a combined product amount.

In a first aspect of the invention, a system for determining individual product amounts of a plurality of chemical reactors contributing to a combined product amount is provided, wherein the system comprises:
a measurements providing unit configured to provide measured individual reactant amounts for each of the plurality of chemical reactors,
an artificial intelligence providing unit configured to provide a trained artificial intelligence for each of the chemical reactors, wherein the provided trained artificial intelligences are trained to provide, upon receiving individual reactant amounts for the chemical reactors as input, individual product amounts of the chemical reactors as output that combine to a combined product amount associated with the individual reactant amounts received as input, and
an individual product amount determining unit configured to determine individual product amounts for the plurality of chemical reactors based on the measured individual reactant amounts and the trained artificial intelligences.

Hence, a plurality of artificial intelligences are used to model the chemical reactors individually, wherein the artificial intelligences are trained such that the individual product amounts provided as output combine to a combined product amount associated with the individual reactant amounts received as input. It has been found that this allows for an accurate determination of the individual product amounts of the plurality of reactors based on their respective individual reactant amounts, wherein the determined individual product amounts can be used for an optimized control of the reactors, thereby allowing for an increased efficiency of the respective production process.

The determined individual product amounts may replace corresponding measurements. Such measurements of the individual product amounts may not be possible if only the combined product amount is supplied for access. And where such measurements are possible, they may no longer be needed when using the presented system.

Controlling a chemical production process in which a plurality of chemical reactors contribute to a combined product amount without being able to measure the individual product amounts of the reactors can be challenging even if all reactors are identical and the supplied combined product amount is known, since the amount of reactants provided to the individual reactors as well as the further process parameters chosen for controlling the reactions running in the individual reactors can differ from each other. The amount of reactants provided to the individual reactors as well as the further process parameters for the plurality of reactors may be chosen differently on purpose for practical reasons. However, even if an identical control is desired, this may only be achievable with a finite accuracy, wherein even relatively small variations in the individual reactant amounts as well as the further process parameters can have relatively large effects on the individual product amounts produced by the individual reactors. An accurate determination of the individual product amounts of the plurality of chemical reactors contributing to the combined product amount provides for richer information based on which the production process can be controlled.

The individual reactant amounts may refer to an amount of one or to respective amounts of more than one of a plurality of reactants, wherein the plurality of reactants are chemically distinguishable from each other. It may be sufficient to measure only the amount of one of the reactants for each of the plurality of chemical reactors. However, particularly for complex chemical reactions, also the amounts of more than one reactant, specifically of all reactants, may be measured for each of the chemical reactors.

The combined product amount may refer to an amount of one of a plurality of products, wherein the plurality of products are chemically distinguishable from each other. The combined product whose amount is referred to herein can particularly be the product whose production is a main purpose of the chemical reactors. The other of the plurality of products may be produced only as a side effect. Nevertheless, also these other products may still be useful, such as for further reactions in further reactors.

The plurality of chemical reactors may be acetylene reactors for producing acetylene. In particular, acetylene, or a raw form thereof which can later be processed to actual acetylene, may be produced in the plurality of chemical reactors from oxygen and natural gas as reactants. Besides acetylene, synthesis gas may be produced. In this particular case, for instance, the measured individual reactant amounts can refer to individual amounts of natural gas and oxygen delivered to each of the plurality of reactors, and the combined product amount can refer to an amount of acetylene produced by the plurality of chemical reactors collectively.

The term “artificial intelligence” is understood herein as including machine learning models of any type. Amongst the artificial intelligences that have been found to be specifically useful for the present purposes are artificial neural networks and regression trees, particularly gradient-boosted trees such as, for instance, XGBoost models. However, it will be understood that these are just particular examples of the types of artificial intelligences that can be used.

The artificial intelligences may particularly be trained such that, upon receiving the individual reactant amounts for the chemical reactors as input, they provide individual product amounts of the chemical reactors as output that add up to the combined product amount. The “combination” may therefore particularly refer to a sum. The amounts of individual products and the combined product may be expressed, for instance, in terms of volume or weight, particularly in terms of a volume or weight flow, i.e. a volume or weight supplied or delivered, respectively, per unit of time.

The association between the individual reactant amounts received by the artificial intelligences as input and the combination of the individual product amounts provided by the artificial intelligences as output may particularly correspond to an assignment made for training the artificial intelligences. For instance, the combined product amount can be associated with the individual reactant amounts received by the artificial intelligences as input in that it has been used in a combined training of the plurality of artificial intelligences as a combined training output to be provided by the artificial intelligences receiving the individual reactant amounts as input. The training data for the combined training of the artificial intelligences may hence comprise, for instance, a) measured individual reactant amounts as training input data, and b) measured combined product amounts as combined training output data. The artificial intelligences can be trained such that the individual product amounts provided as output upon receiving the measured individual reactant amounts used as training input data add up to the measured combined product amounts used as combined training output data.

Data “pairs” of a) measured individual reactant amounts and b) measured combined product amounts can also be acquired at a time at which the production process is to be controlled, i.e. at which a state of the production process is to be checked and/or changed. The association between the individual reactant amounts received by the artificial intelligences as input and the combination of the individual product amounts provided by the artificial intelligences as output may hence also correspond to an assignment between a) individual reactant amounts measured for the plurality of reactors at a time at which the production process is to be controlled, and b) a combined product amount that can be expected and/or is measured at this time. In other words, the trained artificial intelligences can be viewed as a model of the “real” data measurable during production, and which characterize the ongoing production process.

It is understood that a perfect training of the artificial intelligences will generally not be possible in practice. Hence, the outputs provided by the trained artificial intelligences may only combine, or add up, approximately to the combined product amount, i.e. the combined product amount associated with the individual reactant amounts received by the artificial intelligences as input. This holds not only in relation to the “real” data, but also for the training data, one reason being that overtraining should be avoided.

The provided trained artificial intelligences can be trained to provide the individual product amounts of the chemical reactors as output upon additionally receiving input values derived from the individual reactant amounts. Even though the additional input values may be derived just from the individual reactant amounts, i.e. without further information, such as in terms of a function depending only on the individual reactant amounts, for instance, it has been found that using such additional input values allows for a more accurate determination of individual product amounts. For instance, the artificial intelligences can receive the individual reactant amounts and additionally a ratio between the individual reactant amounts for the respective chemical reactors as input. In the case of acetylene production from natural gas and oxygen, for instance, it may be preferred to use artificial intelligences that do not only receive the amounts of natural gas and oxygen as input, but additionally the ratios between the respective amounts of oxygen and natural gas for the plurality of chemical reactors. That such an additional input can increase the performance of the system is somewhat surprising, since the ratios do not carry more information than the measured individual oxygen and natural gas amounts themselves, as they can be computed by dividing one of the measured individual amounts by the other.

For determining control parameters for chemical reactions in a plurality of chemical reactors contributing to a combined product amount, a system may be used that comprises:
the system for determining individual product amounts of the plurality of chemical reactors as defined above, and
a control parameter determining unit configured to determine control parameters for the chemical reactions in the plurality of chemical reactors based on the determined individual product amounts.

Since the individual product amounts can be accurately determined using the plurality of individual artificial intelligences, control parameters can be determined that allow for an optimized control of the chemical reactors, and hence for a more efficient production.

In particular, the control parameter determining unit can be configured to determine individual reactant amounts to be delivered to the plurality of chemical reactors and/or further process parameters for the plurality of chemical reactions based on the determined individual product amounts. Hence, the determined control parameters can particularly correspond to individual reactant amounts to be delivered to the plurality of chemical reactors and/or further process parameters for the plurality of chemical reactions. It is understood that the plurality of reactions can be substantially chemically identical, wherein “the plurality” just arises from the fact that the reactions are run in different reactors, thereby leading to small variations.

A human operator may control the plurality of chemical reactors based on the determined control parameters. Alternatively, a control system for controlling the plurality of chemical reactors may be provided, wherein the control system may be configured to control the plurality of chemical reactors based on the determined control parameters. A control of a reactor based on determined control parameters may refer to an adjustment of actually observed control parameters to the determined ones. For instance, a flow of one or more reactants to the reactor may be increased or reduced. The determined control parameters may particularly refer to target control parameters.

The control parameter determining unit may be configured to determine the control parameters based further on the measured individual reactant amounts and/or a measured combined product amount. In this way, a current state of the respective reactors can be taken into account. This may make the determination of the control parameters more efficient, since the state of a reactor can limit the control parameters achievable within a desired window of time, such that other control parameters do not need to be considered as candidates.

Additionally or alternatively, the control parameter determining unit may be configured to determine the control parameters based on the trained artificial intelligences. For instance, the trained artificial intelligences may be used to determine individual product amounts for candidate individual reactant amounts. Those candidate individual reactant amounts which result, by use of the trained artificial intelligences, in the most favorable individual product amounts may then be chosen as the individual reactant amounts actually to be delivered to the plurality of chemical reactors. The term “most favorable”, as will be understood, can refer to any measure for assessing the performance of the plurality of chemical reactors. For instance, the “most favorable” individual product amounts may not necessarily be the highest, but could also be those satisfying a predefined relation with respect to the candidate individual reactant amounts.

The control parameter determining unit can be configured to determine the control parameters for the chemical reactions such that a combined amount of at least one of the reactants for the plurality of chemical reactors is minimized without decreasing the combined product amount. In this way, a resource-saving chemical production can be achieved. Moreover, also the costs for supplying the at least one reactant, and therefore the overall production costs, can be minimized.

In particular, the control unit can be configured to control the chemical reactions such that a combined amount of at least one of the reactants for the plurality of chemical reactors is minimized without changing the combined product amount. Hence, in such embodiments, the combined product amount is not only not decreased, but it is also not increased. In other words, it is maintained.

In fact, the control unit may also be configured not to minimize the combined amount of a particular reactant, but to minimize the combined production costs. Since the costs for supplying the different reactants and for controlling the chemical reactions according to particular process parameters, which may include a particular energy consumption, may not stay constant over time, minimizing the combined production costs does not necessarily correspond to a minimization of the amount of a particular reactant.

It has been found that the dependence of the combined product amount on the plurality of individual reactant amounts and/or further process parameters is generally relatively complex and, when understood as a function on the space of possible reactant amounts and/or further process parameters for the plurality of chemical reactors, typically comprises several local minima. It is therefore preferred that the respective minimization is carried out globally, i.e. globally in the space of possible reactant amounts and/or further process parameters for the plurality of chemical reactors. In particular, an evolutionary algorithm, such as a differential evolution or a genetic algorithm, for instance, can be used for the respective minimization.

In an embodiment, the control parameter determining unit may be configured to determine the control parameters by minimizing a quantity expressible by the function

$${f}_{cost}^{DE} ( X ( t ) , b ) := {b}^{T} X ( t ) p \qquad ( 1 a )$$

under the constraints

$$y ( t ) \cdot b \geq y , \qquad ( 1 b )$$

$$max ( {s}_{1} {O}_{p}^{k} , {L}_{p}^{k} ) \leq {X}_{p}^{k} ( t ) ∀ k , p , and \qquad ( 1 c )$$

$$min ( {s}_{2} {O}_{p}^{k} , {U}_{p}^{k} ) \geq {X}_{p}^{k} ( t ) ∀ k , p , \qquad ( 1 d )$$

wherein X(t)∈ [symbol] ^{K×P} contains the individual amounts of the P reactants for the K reactors at a time t, p∈ [symbol] ^{P} contains costs of the P reactants, b∈{0, 1}^{K} indicates for the K reactors whether they are active or not, y(t) refers to the individual product amounts of the K reactors determined by the trained artificial intelligences for the individual reactant amounts X(t), y refers to a desired minimum combined product amount, s₁ and s₂ are predefined constants, O∈ [symbol] ^{K×P} contains measured individual reactant amounts, and L, U∈ [symbol] ^{K×P} contain predefined limits for the individual reactant amounts. It will be understood that k is an integer row index running from 1 to K, and p is an integer column index running from 1 to P. Equations (1a) to (1d) have been found to form a suitable starting point for a differential evolution (“DE”). By using these equations, it can particularly also be taken into account that there may be technical limits in practice to how fast a flow of reactants supplied to the individual chemical reactors can be changed, wherein these limits may be reflected in a certain fraction of a current (measured) flow rate to which the flow rate can at most be decreased or increased in a given control cycle, as representable by s₁ and s₂, respectively.

Alternatively, for instance, a genetic algorithm (“GA”) can be used to optimize the control parameters. The control parameter determining unit may then particularly be configured to determine the control parameters by minimizing a quantity expressible by the function

$${f}_{cost}^{GA} ( X ( t ) , b ) := {b}^{T} X ( t ) p + w max ( 0 , y - y ( t ) \cdot b ) \qquad ( 2 a )$$

under the constraints

$$max ( {s}_{1} {O}_{p}^{k} , {L}_{p}^{k} ) \leq {X}_{p}^{k} ( t ) ∀ k , p , and \qquad ( 2 b )$$

$$min ( {s}_{2} {O}_{p}^{k} , {U}_{p}^{k} ) \geq {X}_{p}^{k} ( t ) ∀ k , p . \qquad ( 2 c )$$

wherein, again, X(t)∈ [symbol] ^{K×P} contains the individual amounts of the P reactants for the K reactors at a time t, p∈ [symbol] ^{P} contains costs of the P reactants, b∈{0, 1}^{K} indicates for the K reactors whether they are active or not, y(t) refers to the individual product amounts of the K reactors determined by the trained artificial intelligences for the individual reactant amounts X(t), y refers to a desired minimum combined product amount, s₁ and s₂ are predefined constants, O∈ [symbol] ^{K×P} contains measured individual reactant amounts, and L, U∈ [symbol] ^{K×P} contain predefined limits for the individual reactant amounts. Additionally, w∈ [symbol] ₊ is a weight indicative of how heavily the constraint known from equation (1b) should now enter the function to be minimized as a penalty. It will again be understood that k is an integer row index running from 1 to K, and p is an integer column index running from 1 to P.

Both differential evolutions and genetic algorithms can be carried out in different variants thereof. Since some of them may allow for a faster and/or more accurate determining of the optimal control parameters, an “optimization on optimization procedures” may be carried out, i.e. an optimization on an ensemble of methods considered to be used for optimizing the control parameters.

As far as a differential evolution is considered for finding the optimal control parameters, a search for its optimal variant can be limited to the variants indicated in below Table 1 (a), in which Nₚₒₚ refers to the size of each population considered, D to the number of control parameters considered, CR to the crossover probability, F to the differential weight and the “strategy” to the evolutionary strategy as used, for instance, in SciPy v1.9.2. As far as a genetic algorithm is considered for finding the optimal control parameters, a search for its optimal variant can be limited to the variants indicated in below Table 1 (b), in which Nₚₒₚ refers again to the size of each population considered, CR again to the crossover probability, MR to the mutation probability, and “crossover” to the type of crossovers considered.

TABLES 1a, b
Parameter choices for a) the differential evolutions (DE,
left) and b) the genetic algorithms (GA, right) considered
for control parameter optimization in an embodiment.

| (1a) | | (1b) | |
|---|---|---|---|
| DE | Considered | GA | Considered |
| Parameter | Choices | Parameter | Choices |
| Nₚₒₚ | {5D, 10D} | Nₚₒₚ | {100, 200} |
| CR | {0.7, 0.9} | CR | {0.5, 0.7} |
| F | {0.5, 0.7, 0.9} | MR | {0.01, 0.1, 0.2} |
| strategy | {rand1bin, best2bin | crossover | {1-point, 2-point, |
| | randtobest1bin} | | uniform} |

In order to carry out an optimization of control parameters in a meaningful way, the control parameter determining unit relies on artificial intelligences that have been previously trained.

Preferably, the trained artificial intelligences are obtainable, i.e. can be obtained, by a training method comprising:
providing measured individual reactant amounts for each of the plurality of chemical reactors and measured combined product amounts of the plurality of chemical reactors that are associated with the measured individual reactant amounts,
providing estimated individual product amounts for each of the plurality of chemical reactors,
providing, for each of the plurality of chemical reactors, an artificial intelligence to be trained,
preliminarily training the provided artificial intelligences such that the preliminarily trained artificial intelligences provide the respective estimated individual product amounts as output upon receiving the measured individual reactant amounts as input,
determining adapted individual product amounts for each of the plurality of chemical reactors in accordance with a prescription expressible by

$$( \begin{matrix}{y}^{′} \\ {y}^{′}\end{matrix} ) = SP ( \begin{matrix}y \\ y\end{matrix} ) , \qquad ( 3 )$$

wherein y∈ [symbol] ^{K}, with K being the number of chemical reactors, refers to the individual product amounts provided as output by the preliminarily trained artificial intelligences upon receiving the measured individual reactant amounts as input, y to the measured combined product amount, y′∈ [symbol] ^{K} to the adapted individual product amounts, P∈ [symbol] ^{K×K+1} and S∈ [symbol] ^{K+1×K}, wherein S has the form

$$S = ( \begin{matrix}1 ... 1 \\ {I}_{K}\end{matrix} ) , \qquad ( 4 )$$

with I_{K} being the identity matrix in K dimensions and each entry in the first row of S being equal to 1, and
supplementarily training the preliminarily trained artificial intelligences such that the supplementarily trained artificial intelligences provide the respective adapted individual product amounts y′ as output upon receiving the measured individual reactant amounts as input.

The above definitions of the preliminary and the supplementary training shall not be misunderstood such that outputs provided by the respectively trained artificial intelligences need to match the respectively aimed-at outputs perfectly. Instead, the aimed-at outputs, i.e. the estimated individual product amounts during preliminary training and the adapted individual product amounts y′ during supplementary training, serve as training output data for the training input data being the measured individual reactant amounts, wherein known training protocols may be followed for each of the preliminary training and the supplementary training, i.e. when considered on their own.

The artificial intelligences could be understood as models relating individual reactant amounts and possibly further input quantities, which could collectively be referred to as x₁, x₂, . . . , x_{P}, to individual product amounts ŷ, wherein the individual product amounts ŷ provided as output by the artificial intelligences change in the course of training, i.e. from the values y resulting from the preliminary training towards more refined values, which are assumed to represent the actual, non-measureable individual product amounts more accurately.

The quantity y′ can be understood as an adapted combined product amount. However, it is preferably treated as only a fictitious combined product amount, since, in contrast to the individual product amounts, the combined product amounts have been measured, wherein these measurements are preferably trusted.

With the given form of S and (shape of) P, above equation (3) for the adapted individual product amounts can be spelled out as

$${y}^{′} = P ( \begin{matrix}y \\ y\end{matrix} ) \qquad ( 5 )$$

$$and$$

$$( \begin{matrix}{y}^{′} \\ {y}^{′}\end{matrix} ) = {Sy}^{′} , \qquad ( 6 )$$

such that due to the form of S it also follows that

$${y}^{′} = {\sum }_{k = 1}^{K} {y}^{′ k} . \qquad ( 7 )$$

This means that the adapted individual product amounts add up to the “fictitiously” adapted combined product amount. Hence, the adapted quantities y′ and y′ behave as it is expected from their “true” correspondents, i.e. from the measured combined product amounts and the respective, non-measurable, individual product amounts. Meanwhile, this will generally not hold for the corresponding vector (y,y)^{T}, as the individual product amounts y arising as outputs from the preliminary training can generally not be expected to already add up to the actual, measured combined product amount y. In case the individual product amounts are expected to combine differently to the combined product amount than by addition, S, particularly its first row, could be adapted accordingly.

The estimated individual product amounts for the plurality of chemical reactors can be provided based on the measured combined product amount and/or the measured individual reactant amounts. In particular, they can be provided so as to combine, i.e. specifically add up, to the measured combined product amount. For instance, if it is measured that the plurality of chemical reactors all receive the same individual reactant amounts, also the individual product amounts can be estimated to be the same, namely the measured combined product amount divided by the number of chemical reactors. This particular estimate could also be referred to as an average. More generally, a breakdown of the measured combined product amount according to the measured individual reactant amounts may be used for estimating the individual product amounts. This is to say that, if it is measured that the plurality of chemical reactors receive different individual reactant amounts, it may be estimated that the individual product amounts relate to the measured combined product amount like the measured individual reactant amounts relate to a combination of the measured individual reactant amounts. A particular one of the reactants may be chosen as a basis for this breakdown. In other words, the estimated individual product amounts may be such that they relate to the measured combined product amount like the individual reactant amounts measured for a particular one of the reactants relate to a combination of the individual reactant amounts measured for this particular one of the reactants. The combinations may particularly refer to sums.

Hence, when denoting the estimated individual product amounts as y and the individual product amounts resulting as outputs from the supplementary training as y″, the sequence \tilde{y}→y→y′→y″ could be regarded as a sequence of successively improved approximations to the unmeasurable actual individual product amounts. Note that, even when the estimated individual product amounts y are chosen so as to add up to the measured combined product amount y, i.e.

$$y = {\sum }_{k = 1}^{K} {\tilde{y}}^{k} ,$$

it can sun not be assumed that the individual product amounts y resulting as outputs from the preliminary training do so. Hence, even then

$$y \neq {\sum }_{k = 1}^{K} {y}^{k}$$

needs to be assumed in general, as the preliminary training will generally have the effect that the outputs provided by the artificial intelligences deviate from the training outputs, thereby finding, as is common for machine learning, a “compromise” therebetween. Of course, it cannot be excluded that, for some individual reactant amounts that have been used as training inputs, the preliminarily trained artificial intelligences provide outputs that match the corresponding training outputs, i.e. the corresponding estimated individual product amounts \tilde{y}, and hence add up to the measured combined product amounts y associated with the individual reactant amounts.

The measured individual reactant amounts and the measured combined product amounts provided in the training method may be measured over time, such that a plurality of individual reactant amounts and associated combined product amounts measured for several points in time are provided, wherein the steps of providing estimated individual product amounts, preliminarily training the artificial intelligences, determining adapted individual product amounts and supplementarily training the artificial intelligences are carried out for the plurality of individual reactant amounts and associated combined product amounts measured for the several points in time.

If the chemical reaction of concern, i.e. each of the chemical reactions in the plurality of chemical reactors, happens fast enough and if the time needed by the individual products from the plurality of reactors to be transported, and along the way combined, to the location at which the combined product amount is measurable is short enough, any time delay can be neglected to a sufficient approximation, i.e. a combined product amount measured for a given point in time may be assigned to the individual reactant amounts measured for this point in time. Otherwise, an assignment between the measured combined product amounts and the measured individual reactant amounts may be applied based on a predetermined time delay.

In case the measurements used for training are acquired over time, some of the quantities used for describing the training method acquire a time dependence. While for practical reasons only measurements for particular points in time may be carried out, such that the time dependence may also be indicated by additional indices, for the sake of presentation the time dependence may nevertheless be represented as if it were continuous in order to distinguish it from indices indicating the chemical reactor/artificial intelligence and the input quantities received by the artificial intelligences. Then, for instance, the measured individual reactant amounts and combined product amounts will be representable as x_{1,2}=x_{1,2}(t) and y=y(t), wherein t indicates the respective measurement times. Accordingly, the preliminary training would result in output quantities y=y(t), wherein the determination of the estimated individual product amounts and the determination of the adapted individual product amounts as defined in above equation (3) could then identically be carried out for all measurement times t, thereby leading to quantities

$$( \begin{matrix}y ′ ( t ) \\ y ′ ( t )\end{matrix} ) ,$$

etc.

While pairs of training input data, i.e. a) measured individual reactant amounts x_{1,2} and possible further input quantities x_{3, . . . ,P}, and b) training output data, i.e. the respective quantities \tilde{y}, y′, SPy″, etc., preferably relate to the same point in time, such that the pairs of training input data and training output data can be conveniently indexed by a same t, it will be understood that that the training input data and the training output data may also stem from different points in time. In other words, the techniques disclosed herein can be generalized to forecasting applications, i.e. applications in which, based on certain measured individual reactant amounts at a first point in time, individual product amounts can be predicted for a second point in time which lies after the first point in time.

The adapted individual product amounts y′ can be determined using

$$P = {( {S}^{T} {W}^{- 1} S )}^{- 1} {S}^{T} {W}^{- 1} , \qquad ( 8 )$$

with W being of any of the forms

$$W ∝ {I}_{K + 1} , \qquad a )$$

$$W ∝ diag ( {\sum }_{t = 1}^{{T}_{tot}} {( {( {e}_{t}^{1} )}^{2} , {( {e}_{t}^{2} )}^{2} , ... , {( {e}_{t}^{K} )}^{2} )}^{T} ) , \qquad b )$$

$$wherein {e}_{t} = {( {e}_{t}^{1} , {e}_{t}^{2} , ... , {e}_{t}^{K} )}^{T}$$

refers to the errors, or deviations, of y, i.e. the individual product amounts provided as output by the preliminarily trained artificial intelligences, with respect to the estimated individual product amounts y determined for measured individual reactant amounts and combined product amounts indicated by t=1 . . . . Tₜₒₜ. Choice b) could also be written as

$$W ∝ diag ( {\sum }_{t = 1}^{{T}_{tot}} {( {( {e}^{1} ( t ) )}^{2} , {( {e}^{2} ( t ) )}^{2} , ... , {( {e}^{K} ( t ) )}^{2} )}^{T} ) .$$

As an alternative to choice b),

$$W ∝ {\sum }_{t = 1}^{{T}_{tot}} {e}_{t} {e}_{t}^{T}$$

could be used, which may also be written as

$$W ∝ {\sum }_{t = 1}^{{T}_{tot}} e ( t ) {e ( t )}^{T} .$$

A further option is to choose

W∝diag(S1_{K}), c)
wherein 1_{K} refers to the K-dimensional vector 1_{K}=(1, . . . , 1)^{T} having only 1's as entries.

It has been found that any of these choices for P allows for a good accuracy of the adapted individual product amounts.

Preferably, the determining of adapted individual product amounts and the supplementary training of the artificial intelligences is being repeated in the training method, wherein in each repetition:
the individual product amounts provided as output by the previously trained artificial intelligences upon receiving the measured individual reactant amounts as input are assumed as individual product amounts to be adapted in order to determine further adapted individual product amounts based thereon, and
the artificial intelligences are supplementarily trained such that the supplementarily trained artificial intelligences provide the further adapted individual product amounts as output upon receiving the measured individual reactant amounts as input.

As mentioned above, the quantity y′ is preferably regarded as a fictitious combined product amount. Correspondingly, it can be discarded between repetitions, meaning that its value as determined in one repetition in the course of determining adapted individual product amounts is not used in the next repetition, i.e. for determining any further adapted individual product amounts. Instead, the respective measured combined product amount can again be used. Hence, when repeating the supplementary training, equation (3) can again be used, wherein y is replaced by the individual product amounts as determined by the artificial intelligences resulting from the previous supplementary training, but without replacing y.

Moreover, for adapting the individual product amounts between the supplementary trainings, an equation corresponding to equation (8) can again be used, particularly with any of the above options a) to c) for W. If option b) is used, the quantities eₜ are then redefined to refer to errors, or deviations, of i) the individual product amounts provided as output by the respective previously supplementarily trained artificial intelligences upon receiving the measured individual reactant amounts as input, with respect to ii) the corresponding individual product amounts used as training outputs for the respective previous supplementary training. Since the estimated individual product amounts serve as training outputs during the preliminary training, it could also be said that for each adaptation the training outputs used in the respective previous training can be used. On the other hand, since, in this embodiment, the training outputs used for the supplementary trainings are the adapted training results of the respective previous training, it could be said that, in the adaptions preparing for a respective next supplementary training, the quantities et refer to errors, or deviations, between current training results and adapted training results of a respective previous training.

The preliminary training, the supplementary training and any repetition of the supplementary training can each be carried out in many ways. For instance, known training protocols may be followed, possibly depending on the type of artificial intelligences used, wherein particularly loss functions may be used whose type is essentially not limited.

While, as outlined above, it may be preferred to train the plurality of artificial intelligences not in a single training, but in several training epochs, similarly or even more preferred embodiments have been found to be realizable using only a single training as long as suitable loss functions are chosen for the single training.

According to one of the embodiments realizable without having to conduct the training in several training epochs as outlined above, the (single) training of the artificial intelligences is carried out using the loss function

$${L}^{L 2} ( \tilde{y} , y ) := \frac{1}{T} [ ( 1 - α ) {\sum }_{t = 1}^{T} {‖ \tilde{y} ( t ) - y ( t ) ‖}_{2}^{2} + α {\sum }_{t = 1}^{T} {( {\sum }_{k = 1}^{K} {\tilde{y}}^{k} ( t ) - {y}^{k} ( t ) )}^{2} ] , \qquad ( 9 )$$

wherein \tilde{y}(t) refers to the estimated individual product amounts for the K reactors at a given time t, y(t) refers to the individual product amounts at the time t as determined by the K artificial intelligences at a given stage of the (single) training, and α is a predefined training parameter.

It will be understood that, in principle, the loss function given by equation (9) could also be used at the different epochs of the step-wise training procedure outlined further above, i.e. for the preliminary training, the supplementary training and any repetition of the supplementary training. While for the preliminary training equation (9) could then be identically used, for the one or more supplementary trainings \tilde{y}(t) could then be replaced in equation (9) by the respective adapted version of the individual product amounts as determined by the respective previously trained artificial intelligences, i.e. by the respective training output quantities used for the plurality of artificial intelligences in the respective training epoch. That is to say, for the original supplementary training, \tilde{y}(t) could then be replaced in equation (9) by the adapted individual product amounts y′(t) as determined from equation (3), and if the supplementary training is repeated as explained above, then \tilde{y}(t) as used in equation (9) could be re-set for each repetition to the respective further adapted individual product amounts, i.e., for instance, to SPy″(t) for the first repetition in the terminology introduced further above.

As will be appreciated from equation (9), the loss function L^{L2}(\tilde{y},y) aims to minimize, with its first term, deviations between a) the training outputs \tilde{y}, which can particularly correspond to the initially estimated individual product amounts in the case of a single training or of the preliminary training epoch in the step-wise training procedure outlined further above, and b) the actual outputs y of the artificial intelligences being trained, and, with its second term, deviations between the corresponding combinations, specifically sums, of a) the training outputs and b) the actual outputs, i.e. a) the entries of y and b) the entries of y. The latter is made apparent by noting that, wherever \tilde{y} refers to estimated individual product amounts, as is the case in a single training, and if the estimated individual product amounts are chosen such that they add up to the measured combined product amount y, the second term simplifies to

$$\frac{α}{T} {\sum }_{t = 1}^{T} {( y - {\sum }_{k = 1}^{K} {y}^{k} ( t ) )}^{2} .$$

Another possible loss function that could particularly be used in the single-training approach, but which could equally well be generalized to the multi-stage training as also indicated above for the loss function from equation (9), is the following:

$${L}^{L 1} ( \tilde{y} , y ) := \frac{1}{T} [ ( 1 - α ) {\sum }_{t = 1}^{T} {‖ \tilde{y} ( t ) - y ( t ) ‖}_{1} + α {\sum }_{t = 1}^{T} \vert {\sum }_{k = 1}^{K} {\tilde{y}}^{k} ( t ) - {y}^{k} ( t ) \vert ] . \qquad ( 10 )$$

This alternative loss function, which is the L1-analogue of the previous one, attributes less importance to large deviations between \tilde{y}(t) and y(t), which can help to avoid overfitting of the artificial intelligences to the \tilde{y}(t).

With trained artificial intelligences at hand, for any newly measured set of individual reactant amounts for the plurality of chemical reactors it is possible to determine corresponding individual product amounts even though it might not be possible to measure them. As already indicated above, this can allow for an improved control of the plurality of chemical reactors. This is because a more refined optimization of the control parameters can be carried out. For instance, as already outlined above, particular evolutionary algorithms can be applied, like a differential evolution or a genetic algorithm, for instance.

It should be noted that an optimization might also be carried out on an ensemble of considered artificial intelligences in order to find the one to be actually implemented. When only artificial intelligences of a given type are considered, this process may be referred to as hyperparameter optimization. When artificial intelligences of more than one type are considered, this optimization may be extended to the artificial intelligences of the different types. Typically, the optimization carried out for the artificial intelligences involves preselecting artificial intelligences of one or more types with different hyperparameters, training them, and then comparing the trained artificial intelligences regarding their performance according to a predefined performance measure. Hence, for instance, to find the artificial intelligences to be used for optimizing the control parameters, artificial neural networks and XGBoost models with different hyperparameters may be preselected, trained, and then compared, wherein then the one among them performing best can be selected to be actually used. The term “performing best” can refer, for instance, to how well the respective artificial intelligence is able to reproduce measured combined product amounts from corresponding measured reactant amounts, i.e. measured validation data.

In the case of using artificial neural networks or XGBoost models as artificial intelligences, the hyperparameters can be limited to the values given in below Tables 2a and 2b, respectively.

TABLES 2a, b
Hyperparameter choices for the artificial intelligences considered in embodiments
with a) artificial neural networks (ANN, left) and b) XGBoost models (XGB, right).

| (2a) | | (2b) | |
|---|---|---|---|
| ANN hyperparameters | Considered Choices | XGB hyperparameters | Considered Choices |
| no. of hidden layers | {1, 2} | nₑₛₜᵢₘₐₜₒᵣ | {1, . . . , 5000} |
| no. of hidden neurons | {10, . . . , 600 | max-depth | {0, . . . , 15} |
| no. of epochs | [1, . . . , 100} | min-child-weight | {1, . . . , 1000} |
| batch size | (32, . . . , 1000} | λ | [0, 100] |
| learning rate | [10⁻⁶, 1] | α | [0, 100] |
| dropout rate | [0, 1] | γ | [0, 100] |
| activation function | {ReLU, PReLU, ELU} | δ | [0, 100] |
| initialization technique | {orthogonal, normal, | η | [0, 1] |
| | uniform, he-normal, | row-sub-sampling | [0, 1] |
| | he-uniform} | colsample-bytree | [0, 1] |
| optimization algorithm | {Adam, AdaDelta, | colsample-bylevel | [0, 1] |
| | AdaG-rad, RMSProp} | colsample-bynode | [0, 1] |
| loss function | {MSE, MAE} | Loss | {MSE, Pseudo-Huber} |

Furthermore, the training of the artificial intelligences and the determining of optimized control parameters may be repeated over time, such as at predefined intervals. In this way, changes in the different chemical reactors and/or their environment may be accounted for. The control parameters for the reactors may then be (re-)set accordingly. Periodic intervals of training the artificial intelligences, optimizing the control parameters and (re-)setting the control parameters to the respective “new” optimal control parameters could be referred to as control cycles. A typical control cycle could have a duration of, for instance, one hour.

In a further aspect, the invention relates to a training system for training a plurality of artificial intelligences to be used for determining individual product amounts of a plurality of chemical reactors contributing to a combined product amount, wherein the training system comprises:
a training data providing unit configured to provide training data, wherein the training data comprise a) training input data corresponding to individual reactant amounts received by the plurality chemical reactors and b) training output data corresponding to combined product amounts associated with the individual reactant amounts provided as input data,
an artificial intelligence providing unit configured to provide, for each for the chemical reactors, an artificial intelligence to be trained, and
a training unit configured to use the training data to train the artificial intelligences in a combined training such that the trained artificial intelligences provide, upon receiving individual reactant amounts for the chemical reactors as input, individual product amounts of the chemical reactors as output that combine to a combined product amount associated with the individual reactant amounts received as input. The training carried out by the training unit can be of any of the types described above.

The invention also relates to a method for determining individual product amounts of a plurality of chemical reactors contributing to a combined product amount, wherein the method comprises:
providing measured individual reactant amounts for each of the plurality of chemical reactors,
providing a trained artificial intelligence for each of the chemical reactors, wherein the provided trained artificial intelligences are trained to provide, upon receiving individual reactant amounts for the chemical reactors as input, individual product amounts of the chemical reactors as output that combine to a combined product amount associated with the individual reactant amounts received as input, and
determining individual product amounts for the plurality of chemical reactors based on the measured individual reactant amounts and the trained artificial intelligences. The method can be carried out by the corresponding system, as described further above, in any of its embodiments.

Another aspect of the invention relates to a training method for training a plurality of artificial intelligences to be used for determining individual product amounts of a plurality of chemical reactors contributing to a combined product amount, wherein the training method comprises:
providing training data, wherein the training data comprise a) training input data corresponding to individual reactant amounts received by the plurality chemical reactors and b) training output data corresponding to combined product amounts associated with the individual reactant amounts provided as input data,
providing, for each for the chemical reactors, an artificial intelligence to be trained, and
training the artificial intelligences in a combined training such that the trained artificial intelligences provide, upon receiving individual reactant amounts for the chemical reactors as input, individual product amounts of the chemical reactors as output that combine to a combined product amount associated with the individual reactant amounts received as input. This method can be carried by the above mentioned training system, in any of its embodiments.

The invention also relates, in an aspect, to a computer program for determining individual product amounts of a plurality of chemical reactors contributing to a combined product amount, wherein the program comprises program code means for causing the above system for determining individual product amounts to carry out the corresponding method for determining individual product amounts.

Moreover, the invention relates, in an aspect, to a computer program for training a plurality of artificial intelligences to be used for determining individual product amounts of a plurality of chemical reactors contributing to a combined product amount, wherein the program comprises program code means for causing the above described training system to carry out the above described training method.

It shall be understood that the aspects described above, specifically the system of claim 1, the method of claim 13 and the computer program of claim 14 as well as the training system, the training method and the corresponding computer program, have similar and/or identical preferred embodiments, in particular as defined in the dependent claims.

It shall be understood that a preferred embodiment of the invention can also be any combination of the dependent claims or above embodiments with the respective independent claim.

These and other aspects of the invention will be apparent from and elucidated with reference to the embodiments described hereinafter.

### BRIEF DESCRIPTION OF DRAWINGS

FIG. 1 shows schematically and exemplarily a facility for acetylene production,

FIG. 2 shows schematically and exemplarily a system for determining individual product amounts,

FIG. 3 shows schematically and exemplarily a plurality of artificial intelligences,

FIGS. 4a, b exemplarily illustrate an increase in production efficiency achievable in an embodiment,

FIGS. 5a, b exemplarily illustrate an increase in production efficiency achievable in a further embodiment, and

FIG. 6 shows schematically and exemplarily a method for determining individual product amounts.

### DETAILED DESCRIPTION OF EMBODIMENTS

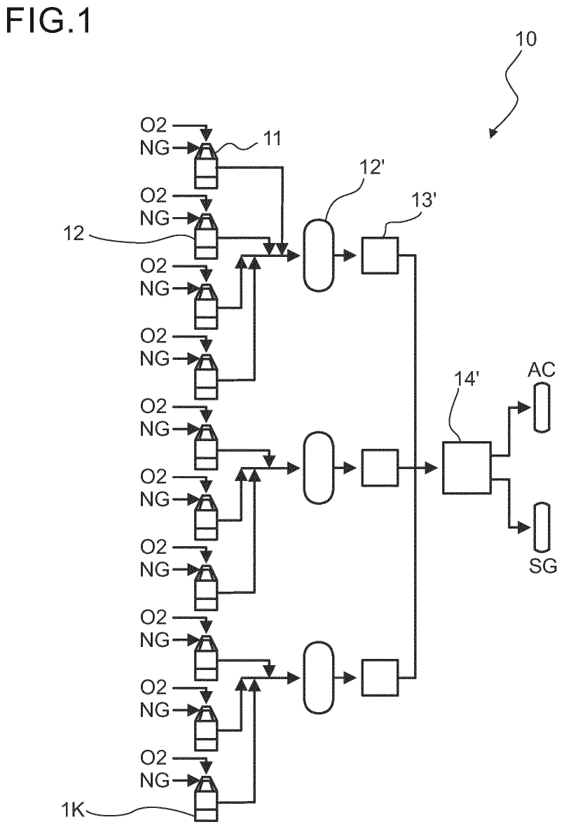

FIG. 1 shows schematically and exemplarily a chemical production facility 10 running a production process. The facility 10 comprises ten chemical reactors 11, 12, . . . , 1K, each of which is fed with oxygen (O2) and natural gas (NG) as reactants. The plurality of chemical reactors 11, 12, . . . , 1K run chemically corresponding reactions, thereby producing chemically corresponding products. In this case, a raw form of acetylene (AC) and additionally synthesis gas (SG) are produced from the reactants O2 and NG. Due to variations in the amount of reactants fed into the different reactors and the behavior of the reactors, for instance, each of the reactors 11, 12, . . . , 1K produces an individual product amount. The output of the individual reactors, i.e. the individual product amounts, are joined via conduits and conducted into fractionating columns 12′. In the illustrated embodiment, three groups of reactors are formed, wherein a separate fractionating column 12′ is provided for each of the three groups. From the fractionating columns 12′, the product, i.e. the already partially combined product amounts, is conducted further to compressors 13′, and from the compressors 13′ to a dedicated device 14′ for separating the product into its chemical constituents, i.e. raw AC and SG. Since the chemical reaction run in the reactors 11, 12, . . . , 1K involves gas cracking, the separating process carried out by the device 14′ could be referred to as cracked gas separation. While a compressor 13′ is still provided for each of the three reactor groups separately, after passing the compressors 13′ the product is joined, such that the whole product amount generated by the ten reactors 11, 12, . . . , 1K enters the device 14′. While not shown in FIG. 1, after the raw AC and the SG are separated from each other in the device 14′, the raw AC is being compressed and thereafter processed to AC in its final form in acid scrubbers, while the SG is conducted into lean gas scrubbers. Since the main purpose of the facility 10 is the production of acetylene, the amount of acetylene being output by the device 14′ would be referred to as “the” combined product amount, while the amount of synthesis gas being output by the device 14′ can be regarded as a side product for the present purposes. Since both the acetylene as well as the synthesis gas produced would generally be used in further chemical production processes, it will nevertheless be understood that the embodiments described herein could also be used when considering instead the amount of synthesis gas produced as the combined product amount whose production is to be optimized.

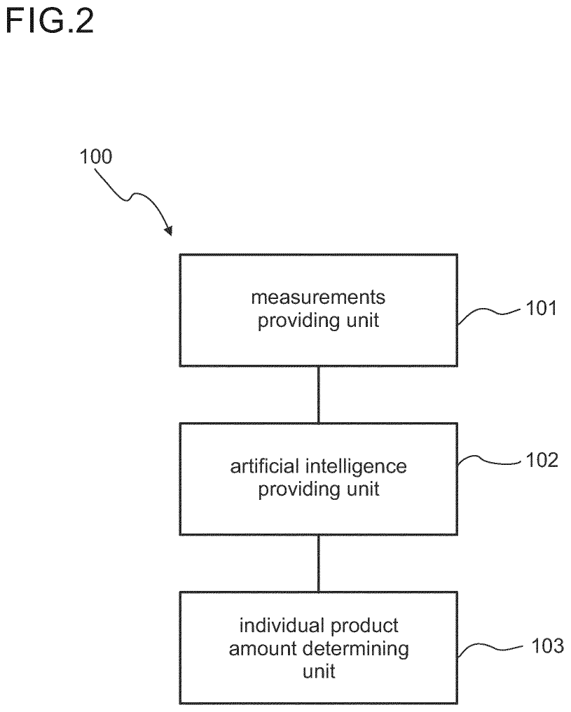

FIG. 2 shows schematically and exemplarily a system 100 for determining individual product amounts of a plurality of chemical reactors contributing to a combined product amount. The system comprises a measurements providing unit 101 configured to provide measured individual reactant amounts for each of the plurality of chemical reactors. Furthermore, the system 100 comprises an artificial intelligence providing unit 102 configured to provide a trained artificial intelligence for each of the chemical reactors, wherein the provided trained artificial intelligences are trained to provide, upon receiving individual reactant amounts for the chemical reactors as input, individual product amounts of the chemical reactors as output that combine to a combined product amount associated with the individual reactant amounts received as input. The system 100 also comprises an individual product amount determining unit 103 configured to determine individual product amounts for the plurality of chemical reactors based on the measured individual reactant amounts and the trained artificial intelligences.

The system 100 can be used to model the production facility 10 shown in FIG. 1. In this way, information can be gained about the reactions running in the individual chemical reactors 11, 12, . . . , 1K even when no measurements of the individual product amounts generated by the respective reactors 11, 12, . . . , 1K, i.e. the individual product streams conducted from the individual reactors 11, 12, . . . , 1K to the fractionating columns 12′, are possible. Often, in production processes like the one illustrated by FIG. 1, a measurement of the individual product amounts generated by the individual chemical reactors 11, 12, . . . , 1K is not possible, in contrast to the measurement of the individual reactant amounts supplied to the individual reactors 11, 12, . . . , 1K, i.e. the amounts of oxygen and natural gas supplied to the reactors 11, 12, . . . , 1K in the example of FIG. 1, and of the combined product amount, i.e. particularly the overall amount of acetylene in the example of FIG. 1. Knowing the individual product amounts allows for an optimal control of the plurality of reactors 11, 12, . . . , 1K, and thereby to increase the efficiency of the overall production process. For instance, a reduction of natural resources consumed for the production can be reduced for a given combined product amount. In the above example of acetylene production, hence, the amount of natural gas needed can be reduced. This cannot only lead to a less costly production and thereby to a competitive advantage, but also to an increased economic and political independence.

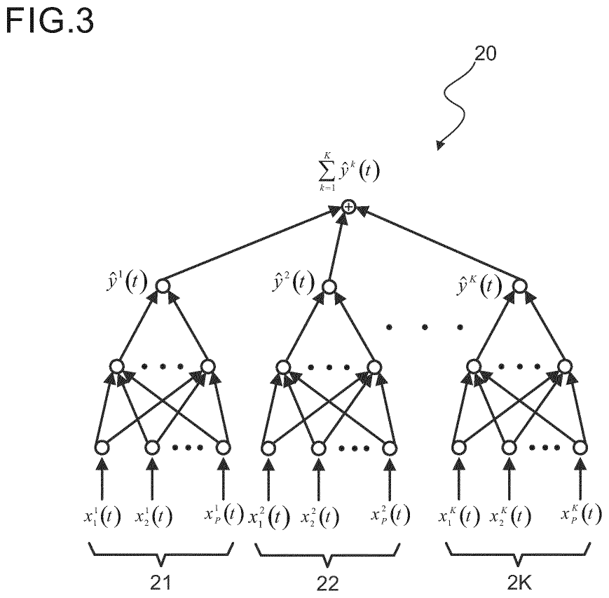

FIG. 3 shows schematically and exemplarily a structure of the artificial intelligences that can be provided by the artificial intelligence providing unit, i.e. which can be used for modelling the individual reactors 11, 12, . . . , 1K. In the illustrated case, the artificial intelligences are structurally identical and have the form of artificial neural networks 21, 22, . . . , 2K. Since, for each of the chemical reactors 11, 12, . . . , 1K, an individual artificial intelligence is provided, there are K artificial intelligences, which can be regarded as forming a larger, joint artificial intelligence 20. In the example shown in FIG. 1, K=10. The artificial neural networks 21, 22, . . . , 2K being “structurally identical” can particularly refer to them sharing the same set of hyperparameters, whereas their training can, of course, lead to different internal parameters of the artificial neural networks, thereby leading to individual models for the respective chemical reactors 11, 12, . . . , 1K.

In the embodiment of FIG. 3, the artificial neural networks are chosen to comprise three layers, i.e. a single hidden layer. Via the input layers, the individual reactant amounts x_{1,2} are received, and via the output layers, the individual product amounts \grave{y} are provided. Moreover, the individual product amounts provided by the K artificial neural networks are added, thereby forming a combined product amount

$${\sum }_{k = 1}^{K} {\hat{y}}^{k}$$

as combined output. This combined output can be regarded as a prediction, or estimation, made by the joint artificial neural network 20 for the combined product amount that would be produced by the facility 10 if its reactors 11, 12, . . . , 1K were fed with the given reactant amounts x_{1,2} received by the artificial intelligences 21, 22, . . . , 2K as input.

In the illustrated embodiment, the artificial neural networks 21, 22, . . . , 2K receive, apart from the individual reactant amounts, one or more further input values x_{3, . . . ,P}, which are derived from the individual reactant amounts x_{1,2}(t). Hence, the number of inputs (P) received by each of the K artificial neural networks can be higher than the number of reactants involved in the chemical reactions. In the context of acetylene production, for instance, it has been found that using, apart from the amounts of oxygen (O2) and natural gas (NG) provided to the individual reactors, also their ratio (e.g., the received amount of O2 divided by the received amount of NG) as a control parameter for controlling the acetylene production, is beneficial.

FIG. 3 illustrates embodiments in which artificial neural networks are used for modelling the reactors 11, 12, . . . , 1K, in other embodiments other types of artificial neural networks can be used. In particular, gradient boosted trees, specifically from the XGBoost library, can be used instead. When using alternative artificial intelligences for modelling the individual reactors 11, 12, . . . , 1K, the internal structure of the artificial intelligences will be different, but they could work with the same input and output data as described above with respect to FIG. 3. Moreover, it may still be preferred that the plurality of artificial intelligence is used for a larger, joint artificial intelligence whose output is formed by combination, particularly addition, of the outputs provided by the individual artificial intelligences.

For training the artificial intelligences, a training system is used that comprises a training data providing unit configured to provide training data, wherein the training data comprise a) training input data corresponding to individual reactant amounts received by the plurality chemical reactors and b) training output data corresponding to combined product amounts associated with the individual reactant amounts provided as input data. The training system further comprises an artificial intelligence providing unit configured to provide, for each for the chemical reactors, an artificial intelligence to be trained, and a training unit configured to use the training data to train the artificial intelligences in a combined training such that the trained artificial intelligences provide, upon receiving individual reactant amounts for the chemical reactors as input, individual product amounts of the chemical reactors as output that combine to a combined product amount associated with the individual reactant amounts received as input.

The training data can be collected via measurements during an ongoing production, such as while the facility 10 shown in FIG. 1 is running. Hence, from such measurements, for instance, pairs of a) measured amounts of oxygen and natural gas supplied to the K reactors 11, 12, . . . , 1K at a given point in time and additionally a ratio between these amounts, and b) an amount of acetylene recovered from the device 14′ at that same point in time can be built, wherein these pairs, collected over time, can be used as training data. In a similar manner, validation data can be acquired, wherein the validation data can be used together with the training data for training the respective artificial intelligences. The training (and validation) data that is collected can be regarded as combined training (and validation) data. While the combined training (and validation) data can be used in a single, combined training of the plurality of artificial intelligences, it may also be preferred to split up the combined training into several stages, wherein at each of the stages, the plurality of artificial intelligences are being trained using individual training data. The respective individual training data may be derived from the combined training data and/or from a result of the training at the respectively preceding training stage. In particular, the training unit of the training system can be configured to implement a training method as follows.

In a first step of the training method, measured individual reactant amounts for each of the plurality of chemical reactors and a measured combined product amount of the plurality of chemical reactors that is associated with the measured individual reactant amounts is provided. In other words, combined training data are provided.

In a second step of the training method, estimated individual product amounts for each of the plurality of chemical reactors are provided. The estimated individual product amounts can correspond to averages of the combined product amounts provided in the first step of the training method, wherein the averages may be weighted according to an amount of one of the reactants supplied to the respective reactors 11, 12, . . . , 1K. For instance, the averages may be weighted according to the amount of natural gas supplied to the individual reactors 11, 12, . . . , 1K. Such a weighting can lead to more accurate estimates, since it can be expected that, the more natural gas is supplied to a reactor, the more acetylene will be contributed by this reactor to the overall produced acetylene amount.

In a third step of the training method, an artificial intelligence to be trained is provided for each of the plurality of chemical reactors 11, 12, . . . , 1K. For instance, artificial neural networks 21, 22, . . . , 2K as illustrated by FIG. 3 can be provided.

In a fourth step of the training method, the artificial intelligences are preliminarily trained such that the preliminarily trained artificial intelligences provide the respective estimated individual product amounts as output upon receiving the measured individual reactant amounts as input. Apart from this choice of training data, the preliminary training of the individual artificial intelligences can be carried out in a manner known for the respective type of artificial intelligence. For instance, a known loss function can be used.

In a fifth step of the training method, adapted individual product amounts for each of the plurality of chemical reactors 11, 12, . . . , 1K are determined in accordance with a prescription expressible by above equations (3) and (4). In particular, for determining the matrix P used in equation (3), equation (8) may be used with any of the choices a) to c) for the matrix W used therein.

Then, in a sixth step of the training method, the preliminarily trained artificial intelligences are supplementarily trained such that the supplementarily trained artificial intelligences provide the respective adapted individual product amounts as output upon receiving the measured individual reactant amounts as input. Again, apart from the choice of training data, also the supplementary training of the individual artificial intelligences can be carried out in a manner known for the respective type of artificial intelligence. For instance, a known loss function can also be used for supplementary training.

In order to collect the training (and validation) data, the measured individual reactant amounts and the measured combined product amount provided in the first step of the training method can be measured over time, such that a plurality of individual reactant amounts and associated combined product amounts measured for several points in time are provided. Then, the steps of providing estimated individual product amounts (second step), preliminarily training the artificial intelligences (fourth step), determining adapted individual product amounts (fifth step) and supplementarily training the artificial intelligences (sixth step) can be carried out for the plurality of individual reactant amounts and associated combined product amounts measured for the several points in time.

Preferably, the fifth step and the sixth step of the training method are being repeated, wherein in each repetition the individual product amounts provided as output by the previously trained artificial intelligences upon receiving the measured individual reactant amounts as input are assumed as individual product amounts to be adapted in order to determine further adapted individual product amounts based thereon, and the artificial intelligences are supplementarily trained such that the supplementarily trained artificial intelligences provide the further adapted individual end product amounts as output upon receiving the respective individual reactant amounts as input. In order to avoid an overtraining of the artificial intelligences an abort criterion may be applied, wherein if the abort criterion is satisfied, the repeated supplementary training is terminated. For instance, the abort criterion can be chosen such that it is satisfied whenever at least one of the following conditions is fulfilled: a) a predetermined number of repetitions has been gone through, b) a performance of the artificial intelligences has not improved for a predetermined number of repetitions, wherein the performance may be measured in terms of a mean absolute error of a sum of the individual outputs of the artificial intelligences with respect to the measured combined product amounts, the mean absolute error being evaluated on the training data set.

In an alternative training method, the combined training is based on the same training data, but not separated into several stages. Instead, a known training protocol may be followed, wherein as loss function for the training one of the functions given in above equations (9) is used (10).

Irrespective of the training protocol followed, the hyperparameters for the respectively used artificial intelligences may be optimized. An optimization of the hyperparameters may, in principle, be carried out such that the artificial intelligences are trained with different choices of hyperparameters, wherein afterwards the different trained artificial intelligences are compared regarding their performance. However, it can be more efficient to make the final selection of hyperparameters before entering the actual training. Therefore, for instance, a hyperparameter optimization may be carried out based on the estimated individual product amounts assumed as training output data. In particular, in the above indicated case of multiple-stage training involving a preliminary training and one or more supplementary trainings, hyperparameter optimization may be carried out on only preliminarily trained artificial intelligences.

Once the artificial intelligences, for some selection of hyperparameters, have been trained, they allow to accurately model the reactors 11, 12, . . . , 1K.

In order to then determine control parameters for the chemical reactions in the plurality of chemical reactors 11, 12, . . . , 1K, a system may be provided that comprises the system 100 for determining individual product amounts of the plurality of chemical reactors, and a control parameter determining unit configured to determine control parameters for the chemical reactions in the plurality of chemical reactors 11, 12, . . . , 1K based on the determined individual product amounts. The control parameter determining unit is preferably configured to determine the control parameters based further on the measured individual reactant amounts and/or a measured combined product amount, more particularly such that a combined amount of at least one of the reactants for the plurality of chemical reactors is minimized without decreasing the combined product amount. In the case of acetylene production, for instance, the amount of natural gas used in the production can be minimized for a given, desired overall amount of acetylene produced. Particularly preferred schemes that can be followed to find optimal control parameters include differential evolutions and genetic algorithms, as discussed above with respect to equations (1a) to (1d) and (2a) to (2c), respectively.

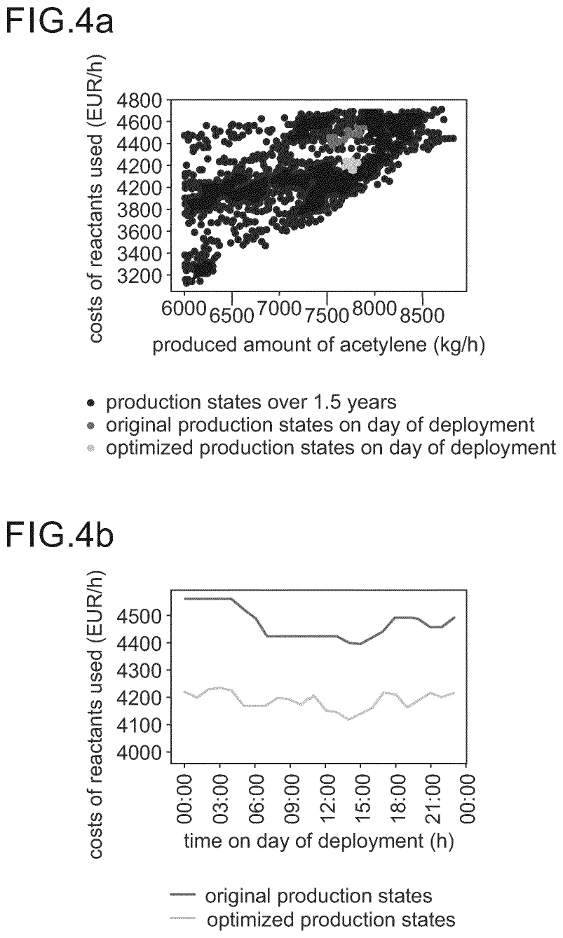

FIG. 4a and FIG. 4b show schematically and exemplarily an increase in efficiency achievable according to the above-described embodiments for an actual production facility 10. FIG. 4a is a scatter plot in which each dot represents a state of the production facility at a given time in the past. On the horizontal axis, the combined amount of produced acetylene is indicated in units of kilograms per hour, and on the vertical axis the money spent on the consumed reactants is indicated in units of Euros (EUR) per hour. As will be understood, for a fixed position in the horizontal direction, the production efficiency is the higher the lower the respective point in the scatter plot lies in the vertical direction. On the other hand, for a fixed position in the vertical direction, the production efficiency is the higher the further right the respective point in the scatter plot lies in the horizontal direction. It can be seen from FIG. 4a that the production efficiency of the considered production facility has varied over the considered time interval, as the points of the scatter plot are relatively distributed. The two smaller point clouds highlighted in FIG. 4a correspond to states of the considered production facility at a same day, wherein the upper of the two point clouds consists of points representing production states without an optimization of control parameters, and the lower of the two point clouds represents production states achievable with the above-described optimization of the control parameters. Hence, it can be observed that a considerable increase in production efficiency was achievable on that day by implementing control parameter optimization as described above. This is further illustrated by FIG. 4b, which is a plot of the money spent on the reactants consumed on the respective day, again in units of Euros per hour, over the course of the day. The upper of the two plotted lines corresponds to the non-optimized production states, whereas the lower of the two lines corresponds to the optimized ones. The gap between the two lines has an approximate width of more than EUR 200 per hour throughout the day, from which a considerable cost saving potential becomes obvious. It is understood that this cost saving potential goes hand in hand with a potential to save resources, particularly natural gas in the case of acetylene production.

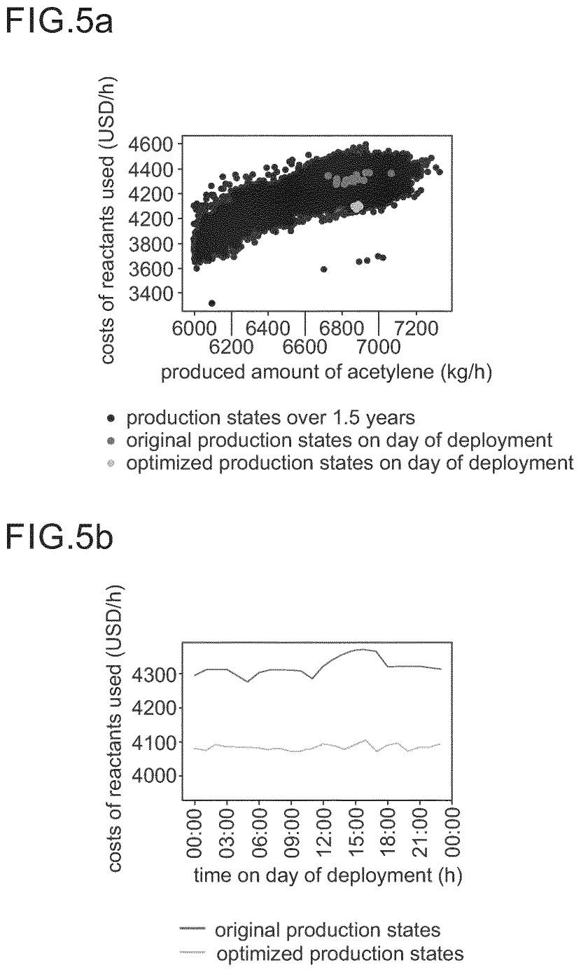

FIG. 5a and FIG. 5b differ from FIG. 4a and FIG. 4b only regarding the database, i.e. regarding the production facility 10 for which the data have been collected. Also for this different production facility a potential to significantly increase the production efficiency by employing control parameter optimization as described above becomes apparent.

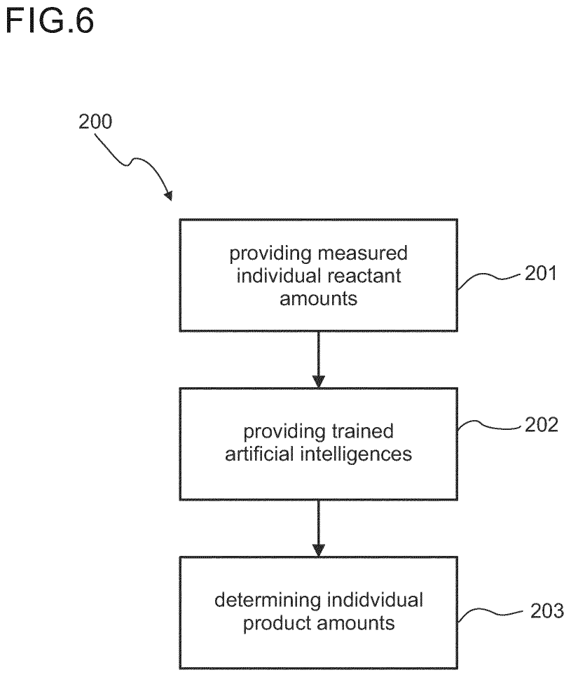

FIG. 6 shows schematically and exemplarily a method 200 for determining individual product amounts of a plurality of chemical reactors contributing to a combined product amount. The method includes a step 201 of providing measured individual reactant amounts for each of the plurality of chemical reactors, and a step 202 of providing a trained artificial intelligence for each of the chemical reactors, wherein the provided trained artificial intelligences are trained to provide, upon receiving individual reactant amounts for the chemical reactors as input, individual product amounts of the chemical reactors as output that combine to a combined product amount associated with the individual reactant amounts received as input. Furthermore, the method 200 includes a step 203 of determining individual product amounts for the plurality of chemical reactors based on the measured individual reactant amounts and the trained artificial intelligences. The method can be carried out, for instance, by the system 100.

Other variations to the disclosed embodiments can be understood and effected by those skilled in the art in practicing the claimed invention, from a study of the drawings, the disclosure, and the appended claims.

In the claims, the word “comprising” does not exclude other elements or steps, and the indefinite article “a” or “an” does not exclude a plurality.

A single unit or device may fulfill the functions of several items recited in the claims. The mere fact that certain measures are recited in mutually different dependent claims does not indicate that a combination of these measures cannot be used to advantage.

Procedures like the providing of reactant amounts or other data, the providing of artificial intelligences, the determining of individual product amounts or control parameters, any training of artificial intelligences, etc., performed by one or several units or devices, can be performed by any other number of units or devices. These procedures can be implemented as program code means of a computer program and/or as dedicated hardware.

A computer program product may be stored/distributed on a suitable medium, such as an optical storage medium or a solid-state medium, supplied together with or as part of other hardware, but may also be distributed in other forms, such as via the Internet or other wired or wireless telecommunication systems.

Any reference signs in the claims should not be construed as limiting the scope.

The invention relates to a system for determining individual product amounts of a plurality of chemical reactors contributing to a combined product amount. The system comprises a measurements providing unit providing measured individual reactant amounts for each reactor, an artificial intelligence providing unit providing artificial intelligences for each reactor that are trained to provide, upon receiving individual reactant amounts for the reactors as input, individual product amounts of the reactors as output that combine to a combined product amount associated with the individual reactant amounts received as input. The system further comprises an individual product amount determining unit determining individual product amounts for the reactors based on the measured individual reactant amounts and the trained artificial intelligences. The system allows for increasing a chemical production efficiency whenever a plurality of reactors contribute to a combined product amount.

1. A system for determining an individual product amount of a plurality of chemical reactors contributing to a combined product amount, wherein the system comprises:
a measurement providing unit configured to provide a measured individual reactant amount for each of the plurality of chemical reactors,
an artificial intelligence providing unit configured to provide a trained artificial intelligence for each of the plurality of chemical reactors, wherein a provided trained artificial intelligence are is trained to provide, upon receiving the measured individual reactant amount for the plurality of chemical reactors as input, the individual product amount of the plurality of chemical reactors as output that combines to the combined product amount associated with the individual reactant amount received as input, and
an individual product amount determining unit configured to determine the individual product amount for the plurality of chemical reactors based on the measured individual reactant amount and the trained artificial intelligence.

2. The system as defined in claim 1, wherein the plurality of chemical reactors are acetylene reactors for producing acetylene.

3. The system as defined in claim 1, wherein the provided trained artificial intelligence are is trained to provide the individual product amount of the plurality of chemical reactors as output upon additionally receiving an input value derived from the individual reactant amount.

4. A system for determining a control parameter for a chemical reaction in a plurality of chemical reactors contributing to a combined product amount, wherein the system comprises:
the system for determining the individual product amount of the plurality of chemical reactors as defined in claim 1,
a control parameter determining unit configured to determine the control parameter for the chemical reaction in the plurality of chemical reactors based on a determined individual product amount.

5. The system as defined in claim 4, wherein the control parameter determining unit is configured to determine the control parameter based further on the measured individual reactant amount and/or a measured combined product amount.

6. The system as defined in claim 4, wherein the control parameter determining unit is configured to determine the control parameter for the chemical reaction such that, wherein a combined amount of at least one of the reactants for the plurality of chemical reactors is minimized without decreasing the combined product amount.

7. The system as defined in claim 1, wherein the trained artificial intelligence is obtainable by a training method comprising:
providing the measured individual reactant amount for each of the plurality of chemical reactors and a measured combined product amount of the plurality of chemical reactors that are associated with the measured individual reactant amount,
providing an estimated individual product amount for each of the plurality of chemical reactors,
providing, for each of the plurality of chemical reactors, an artificial intelligence to be trained,
preliminarily training the provided artificial intelligence, wherein a preliminarily trained artificial intelligence provides a respective estimated individual product amount as output upon receiving the measured individual reactant amount as input,
determining an adapted individual product amount for each of the plurality of chemical reactors in accordance with a prescription expressible by
$$( \begin{matrix}{y}^{′} \\ {y}^{′}\end{matrix} ) = SP ( \begin{matrix}y \\ y\end{matrix} ) ,$$
wherein y∈ [symbol] ^{K}, with K being a number of the plurality of chemical reactors, refers to the individual product amount provided as output by the preliminarily trained artificial intelligence upon receiving the measured individual reactant amount as input, y to the measured combined product amount, y′∈ [symbol] ^{K} to the adapted individual product amount, P∈ [symbol] ^{K×K+1} and S∈ [symbol] ^{K+1×K}, wherein S has a form
$$S = ( \begin{matrix}1 ... 1 \\ {I}_{K}\end{matrix} ) ,$$
with I_{K} being an identity matrix in K dimension and each entry in a first row of S being equal to 1, and
supplementarily training the preliminarily trained artificial intelligence, wherein a supplementarily trained artificial intelligence provides a respective adapted individual product amount as output upon receiving the measured individual reactant amount as input.

8. The system as defined in claim 7, wherein the measured individual reactant amount and the measured combined product amount provided in the training method are measured over time, wherein a plurality of individual reactant amount and an associated combined product amount measured for several points in time are provided, wherein providing the estimated individual product amount, preliminarily training an artificial intelligence, determining the adapted individual product amount and supplementarily training the artificial intelligence are carried out for the plurality of individual reactant amount and the associated combined product amount measured for the several points in time.

9. The system as defined in claim 8, wherein the adapted individual product amount is determined with
$$P = {( {S}^{T} {W}^{- 1} S )}^{- 1} {S}^{T} {W}^{- 1} ,$$
with Wₕ being of any of forms
$$W ∝ {I}_{K + 1} , \qquad a )$$
$$W ∝ diag ( {\sum }_{t = 1}^{{T}_{tot}} {( {( {e}_{t}^{1} )}^{2} , {( {e}_{t}^{2} )}^{2} , ... , {( {e}_{t}^{K} )}^{2} )}^{T} ) , \qquad b )$$
$$wherein {e}_{t} = {( {e}_{t}^{1} , {e}_{t}^{2} , ... , {e}_{t}^{K} )}^{T}$$
refers to an error of y with respect to the estimated individual product amount determined for the measured individual reactant amount and the combined product amount indicated by t=1 . . . Tₜₒₜ, and
Wₕ∝diag(S1_{K}), c)
wherein 1_{K} refers to a K-dimensional vector 1_{K}=(1, . . . , 1)^{T} having only 1's as entries.

10. The system as defined in claim 8, wherein the determining of the adapted individual product amount and supplementary training of the artificial intelligence is being repeated in the training method, wherein in each repetition:
the individual product amount provided as output by previously trained artificial intelligence upon receiving the measured individual reactant amount as input is assumed as the individual product amount to be adapted in order to determine a further adapted individual product amount based thereon, and
the artificial intelligence is supplementarily trained, wherein the supplementarily trained artificial intelligence provides a further adapted individual end product amount as output upon receiving a respective individual reactant amount as input.

11. The system as defined by claim 4, wherein the control parameter determining unit is configured to determine the control parameter by minimizing a quantity expressible by a function
$${f}_{cost}^{DE} ( X ( t ) , b ) := {b}^{T} X ( t ) p$$
under constraints
$$y ( t ) \cdot b \geq y ,$$
$$max ( {s}_{1} {O}_{p}^{k} , {L}_{p}^{k} ) \leq {X}_{p}^{k} ( t ) ∀ k , p , and$$
$$min ( {s}_{2} {O}_{p}^{k} , {U}_{p}^{k} ) \geq {X}_{p}^{k} ( t ) ∀ k , p ,$$
wherein X(t)∈ [symbol] ^{K×P} contains comprises an individual amount of a P reactant for a K reactor at a time t, p∈ [symbol] ^{P} comprises a cost of the P reactant, b∈{0, 1}^{K} indicates for the K reactor whether they are active or not, y(t) refers to the individual product amount of the K reactor determined by the trained artificial intelligence for the individual reactant amount X(t), y refers to a desired minimum combined product amount, s₁ and s₂ are predefined constants, O∈ [symbol] ^{K×P} comprises the measured individual reactant amount, and L, U∈ [symbol] ^{K×P} comprise a predefined limit for the individual reactant amount, or wherein the control parameter determining unit is configured to determine the control parameter by minimizing a quantity expressible by the function
$${f}_{cost}^{GA} ( X ( t ) , b ) := {b}^{T} X ( t ) p + w max ( 0 , y - y ( t ) \cdot b )$$
under the constraints
$$max ( {s}_{1} {O}_{p}^{k} , {L}_{p}^{k} ) \leq {X}_{p}^{k} ( t ) ∀ k , p , and$$
$$min ( {s}_{2} {O}_{p}^{k} , {U}_{p}^{k} ) \geq {X}_{p}^{k} ( t ) ∀ k , p .$$
wherein, again, X(t)∈ [symbol] ^{K×P} comprises the individual amount of the P reactant for the K reactor at a time t, p∈ [symbol] ^{P} comprises cost of the P reactant, b∈{0, 1}^{K} indicates for the K reactor whether they are active or not, y(t) refers to the individual product amount of the K reactor determined by the trained artificial intelligence for the individual reactant amount X(t), y refers to the desired minimum combined product amount, s₁ and s₂ are the predefined constants, O∈ [symbol] ^{K×P} comprises the measured individual reactant amount, and L, U∈ [symbol] ^{K×P} comprise the predefined limit for the individual reactant amount, and w∈ [symbol] ₊ is a predefined weight.

12. The system as defined in claim 1, wherein training of an artificial intelligence is carried out with a loss function
$${L}^{L 2} ( \tilde{y} , y ) := \frac{1}{T} [ ( 1 - α ) {\sum }_{t = 1}^{T} {‖ \tilde{y} ( t ) - y ( t ) ‖}_{2}^{2} + α {\sum }_{t = 1}^{T} {( {\sum }_{k = 1}^{K} {\tilde{y}}^{k} ( t ) - {y}^{k} ( t ) )}^{2} ] ,$$
or the loss function
$${L}^{L 1} ( \tilde{y} , y ) := \frac{1}{T} [ ( 1 - α ) {\sum }_{t = 1}^{T} {‖ \tilde{y} ( t ) - y ( t ) ‖}_{1} + α {\sum }_{t = 1}^{T} \vert {\sum }_{k = 1}^{K} {\tilde{y}}^{k} ( t ) - {y}^{k} ( t ) \vert ] ,$$
wherein \tilde{y}(t) refers to an estimated individual product amount for a K reactor at a given time t, y(t) refers to the individual product amount at a time t as determined by K artificial intelligence, and α is a predefined training parameter.

13. A method for determining an individual product amount of a plurality of chemical reactors contributing to a combined product amount, wherein the method comprises:
providing a measured individual reactant amount for each of the plurality of chemical reactors,
providing a trained artificial intelligence for each of the plurality of chemical reactors, wherein a provided trained artificial intelligence is trained to provide, upon receiving an individual reactant amount for the plurality of chemical reactors as input, the individual product amount of the plurality of chemical reactors as output that combines to a combined product amount associated with the individual reactant amount received as input, and
determining the individual product amount for the plurality of chemical reactors based on the measured individual reactant amount and the trained artificial intelligence.

14. A computer program for determining an individual product amount of a plurality of chemical reactors contributing to a combined product amount, wherein the program comprises program code for causing the system as defined in claim 1 to carry out a method for determining the individual product amount of the plurality of chemical reactors contributing to the combined product amount, wherein the method comprises:
providing the measured individual reactant amount for each of the plurality of chemical reactors,
providing the trained artificial intelligence for each of the plurality chemical reactors, wherein the provided trained artificial intelligence is trained to provide, upon receiving the individual reactant amount for the plurality of chemical reactors as input, the individual product amount of the plurality of chemical reactors as output that combines to the combined product amount associated with the individual reactant amount received as input, and
determining the individual product amount for the plurality of chemical reactors based on the measured individual reactant amount and the trained artificial intelligence.
